(19) United States
(12) Patent Application Publication
(10) Pub. No.: US 2024/0071784 A1
(43) Pub. Date: Feb. 29, 2024

(54) CUTTING APPARATUS

(71) Applicant: DISCO CORPORATION, Tokyo (JP)

(72) Inventor: Kenji TAKENOUCHI, Tokyo (JP)

(21) Appl. No.: 18/366,182

(22) Filed: Aug. 7, 2023

(30) Foreign Application Priority Data
Aug. 29, 2022 (JP) 2022-135611

(51) Int. Cl. H01L 21/67; B26D 1/14; B26D 7/08

(52) U.S. Cl. CPC H01L 21/67092; B26D 1/141; B26D 7/088

(57) ABSTRACT

A cutting apparatus includes a cutting liquid supply nozzle disposed adjacent to a cutting unit, for supplying a cutting liquid to a point of contact between a cutting blade and a workpiece, and a rust inhibitor supply nozzle for supplying a rust inhibitor to the workpiece to prevent electrodes of devices divided from the workpiece from being rusted, the rust inhibitor supply nozzle having a length along a Y-axis in excess of the width of the workpiece along the Y-axis.

### BACKGROUND OF THE INVENTION

### Field of the Invention

The present invention relates to a cutting apparatus for cutting a workpiece having a plurality of devices including electrodes constructed in respective areas demarcated on a face side thereof by a grid of projected dicing lines established on the face side.

### Description of the Related Art

Wafers where a plurality of devices such as integrated circuits (ICs) and large-scale integration (LSI) circuits are constructed in respective areas demarcated on a face side thereof by a grid of projected dicing lines are divided into individual device chips by a cutting apparatus having a rotatable cutting blade. The device chips produced by dividing those wafers will be used in electric appliances including cellular phones, personal computers, etc.

The cutting apparatus includes a chuck table for holding a wafer thereon, a cutting unit having a rotatable cutting blade for cutting the wafer held on the chuck table, an X-axis feed mechanism for cutting-feeding the chuck table and the cutting unit relatively to each other along an X-axis, and a Y-axis feed mechanism for indexing-feeding the chuck table and the cutting unit relatively to each other along a Y-axis perpendicular to the X-axis. The cutting apparatus is capable of dividing the wafer highly accurately into individual device chips.

When the wafer is cut by the cutting blade, swarf, i.e., contaminants, cut from the wafer floats over and deposits on the face side of the wafer, tending to lower the quality of the devices. There has been proposed a technology in which cleaning water is supplied to the face side of a wafer to wash away swarf from the wafer, thereby preventing the swarf from being deposited on device chips produced from the wafer (see, for example, JP 2014-121738A).

### SUMMARY OF THE INVENTION

When a packaged substrate such as a quad flat non-leaded (QFN) package is cut into device chips, the devices of the device chips have their electrode pads oxidized and rusted over time, tending to lower the quality of the devices.

The problem can occur not only when packaged substrates such as QFN are cut, but also when semiconductor wafers having devices with electrodes disposed on their face sides are cut.

It is therefore an object of the present invention to provide a cutting apparatus that is capable of preventing swarf from being deposited on devices on a workpiece cut by the cutting apparatus and also of preventing electrodes of the devices from being oxidized and rusted.

In accordance with an aspect of the present invention, there is provided a cutting apparatus including a chuck table for holding thereon a workpiece having a plurality of devices including electrodes that are constructed in respective areas demarcated on a face side of the workpiece by a plurality of projected dicing lines, a cutting unit having a rotatable cutting blade for cutting the workpiece held on the chuck table, an X-axis feed mechanism for cutting-feeding the chuck table and the cutting unit relatively to each other along an X-axis, a Y-axis feed mechanism for indexing-feeding the chuck table and the cutting unit relatively to each other along a Y-axis perpendicular to the X-axis, a cutting liquid supply nozzle disposed adjacent to the cutting unit, for supplying a cutting liquid to a point of contact between the cutting blade and the workpiece, and a rust inhibitor supply nozzle for supplying a rust inhibitor to the workpiece on the chuck table to prevent the electrodes of the devices from being rusted, the rust inhibitor supply nozzle having a length along the Y-axis in excess of the width of the workpiece along the Y-axis.

Preferably, the cutting liquid supply nozzle supplies pure water or a mixture of an organic acid and an oxidizing agent as the cutting liquid.

The cutting apparatus according to the present invention prevents electrodes of devices from being oxidized and rusted even when time has elapsed after a packaged substrate having QFN devices or the like as the devices was cut by the cutting apparatus, thereby eliminating the problem of a reduction in the quality of the devices.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a cutting apparatus according to an embodiment of the present invention;

FIG. 2 is an enlarged perspective view of a cutting unit of the cutting apparatus illustrated in FIG. 1;

FIG. 3 is a plan view of a rust inhibitor supply nozzle illustrated in FIG. 2 and a wafer;

FIG. 4 is an enlarged perspective view illustrating the manner in which a cutting process is carried out on the cutting apparatus; and

FIG. 5 is a plan view illustrating the manner in which the cutting process is carried out on the cutting apparatus.

### DETAILED DESCRIPTION OF THE PREFERRED EMBODIMENT

A cutting apparatus according to a preferred embodiment of the present invention will hereinafter be described with reference to the accompanying drawings.

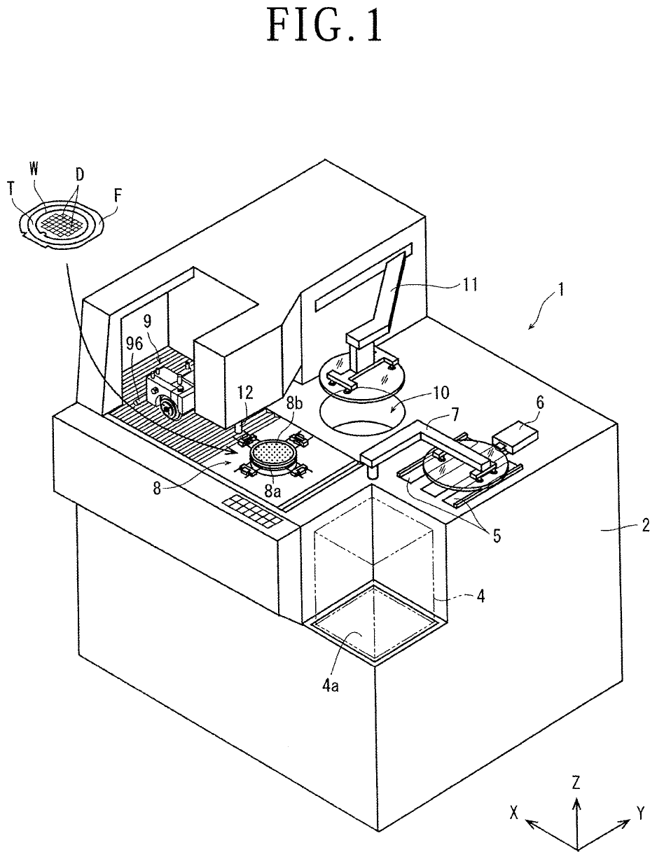

The cutting apparatus is illustrated in FIGS. 1 through 5 of the accompanying drawings with reference to an XYZ coordinate system having an X-axis, a Y-axis, and a Z-axis that extend perpendicularly to each other. The X-axis, the Y-axis, and the Z-axis are indicated respectively by arrows X, Y, and Z.

FIG. 1 illustrates, in perspective, the cutting apparatus, denoted by 1, according to the present embodiment. As illustrated in FIG. 1, a workpiece to be processed, i.e., cut, by the cutting apparatus 1 includes a wafer W of silicon (Si) having a plurality of devices D including a plurality of electrodes, not illustrated, on their face sides. The wafer W is held on an annular frame F by an adhesive tape T.

The cutting apparatus 1 includes a cassette 4, indicated by the two-dot-and-dash lines, for storing a plurality of wafers W therein, a temporary support table 5 for temporarily supporting a wafer W unloaded from the cassette W, an unloading and loading unit 6 for unloading a wafer W from the cassette 4 onto the temporary support table 5 and loading a wafer W from the temporary support table 5 into the cassette 4, a delivery unit 7 for attracting a wafer W unloaded onto the temporary support table 5 under suction and delivering the wafer W with a swing motion onto a holding surface 8b of a chuck table 8a of a holding unit 8, a cutting unit 9 for cutting a wafer W held under suction on the holding surface 8b of the chuck table 8a, a cleaning unit 10, the details of which are omitted from illustration, for cleaning a wafer W that has been cut by the cutting unit 9, another delivery unit 11 for delivering a wafer W cut by the cutting unit 9 from the chuck table 8a to the cleaning unit 10, an image capturing unit 12 for capturing an image of a wafer W on the chuck table 8a, and a controller, not illustrated. The cassette 4 is placed on a cassette table 4a that is vertically movable by a lifting and lowering unit, not illustrated. When a wafer W is to be unloaded from the cassette 4 by the unloading and loading unit 6, the cassette 4 is adjusted to a desired height by the lifting and lowering unit. The cutting apparatus 1 has an apparatus housing 2 that supports the components thereof that have been described above. The apparatus housing 2 accommodates therein an X-axis feed mechanism, not illustrated, for processing-feeding, i.e., cutting-feeding, the chuck table 8a along an X-axis, and a Y-axis feed mechanism, not illustrated, for indexing-feeding the cutting unit 9 along a Y-axis perpendicular to the X-axis.

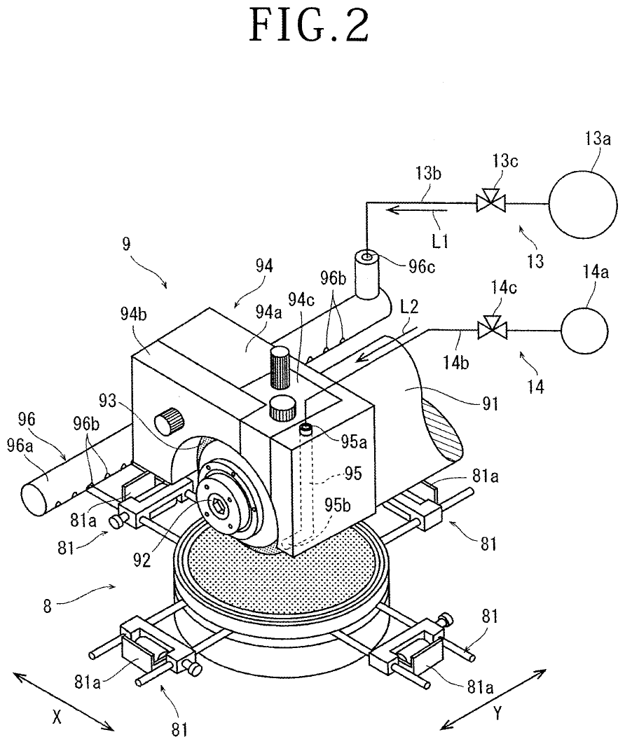

The cutting unit 9 of the cutting apparatus 1 illustrated in FIG. 1 will be described in specific detail with reference to FIG. 2. FIG. 2 illustrates, in enlarged perspective, major parts of the cutting unit 9 and the holding unit 8 that has been moved to a position directly below the cutting unit 9. As illustrated in FIG. 2, the cutting unit 9 includes a spindle housing 91 extending along the Y-axis, a spindle 92 rotatably supported in the spindle housing 91, an annular cutting blade 93 detachably supported on a front end of the spindle 92, a cover 94 mounted on a distal end of the spindle housing 91 and covering the cutting blade 93, a cutting liquid supply nozzle 95, indicated by the broken lines, for supplying a cutting liquid L2 to the point of contact between the cutting blade 93 and a wafer W held on the holding unit 8, and a rust inhibitor supply nozzle 96 for supplying a rust inhibitor L1, to be described in detail later, for preventing the electrodes of the devices D on the wafer W from being rusted. The spindle 92 is rotated about its central axis along the Y-axis by an electric motor, not illustrated, connected to a rear end of the spindle 92. The cutting apparatus 1 according to the present embodiment includes, in addition to the Y-axis feed mechanism, a Z-axis feed mechanism, not illustrated, for incising-feeding the cutting unit 9 along the Z-axis to cause the cutting blade 93 to cut into the wafer W held on the holding unit 8.

As illustrated in FIG. 2, the cover 94 includes a first cover member 94a fixed to the distal end of the spindle housing 91, a second cover member 94b fastened by a screw to a front surface of the first cover member 94a, and a cutting blade detecting block 94c fastened by a screw to the first cover member 94a from an upper surface thereof. The cutting blade detecting block 94c includes a blade sensor, not illustrated, for detecting wear and chips on an outer circumferential edge portion of the cutting blade 93.

The rust inhibitor supply nozzle 96 is disposed adjacent to the cutting unit 9. According to the present embodiment, the rust inhibitor supply nozzle 96 includes a hollow cylindrical body 96a extending along the Y-axis, a plurality of ejection ports 96b defined in the hollow cylindrical body 96a and oriented obliquely downwardly toward the wafer W on the holding unit 8, for ejecting the rust inhibitor L1 toward the wafer W on the holding unit 8, and a rust inhibitor inlet 96c defined in a rear end of the hollow cylindrical body 96a. A rust inhibitor supply unit 13 for supplying the rust inhibitor L1 is fluidly connected to the rust inhibitor inlet 96c. The rust inhibitor supply nozzle 96 is fixed to the cover 94 or the spindle housing 91 by a fixing member, not illustrated, for movement in unison with the cutting unit 9.

The rust inhibitor supply unit 13 includes a rust inhibitor storage tank 13a for storing the rust inhibitor L1, a rust inhibitor path 13b interconnecting the rust inhibitor storage tank 13a and the rust inhibitor inlet 96c, and an on/off valve 13c for selectively opening and closing the rust inhibitor path 13b. The rust inhibitor storage tank 13a includes a pump, not illustrated, for delivering the rust inhibitor L1 from the rust inhibitor storage tank 13a into the rust inhibitor path 13b. When the pump is actuated and the on/off valve 13c is opened, the rust inhibitor L1 is supplied from the rust inhibitor storage tank 13a through the rust inhibitor path 13b and the rust inhibitor inlet 96c into the rust inhibitor supply nozzle 96, from which the rust inhibitor L1 is ejected through the ejection ports 96b.

The cutting liquid supply nozzle 95, indicated by the broken lines in FIG. 2, is disposed in the cutting unit 9. According to the present embodiment, the cutting liquid supply nozzle 95 is constructed in the first cover member 94a, and supplies the cutting liquid L2 introduced from a cutting liquid inlet 95a thereof through an ejection port 95b thereof to the point of contact between the cutting blade 93 and the wafer W to be cut thereby. A cutting liquid supply unit 14 is fluidly connected to the cutting liquid inlet 95a. The cutting liquid supply unit 14 includes a cutting liquid storage tank 14a for storing the cutting liquid L2, a cutting liquid path 14b interconnecting the cutting liquid storage tank 14a and the cutting liquid inlet 95a, and an on/off valve 14c for selectively opening and closing the cutting liquid path 14b. The cutting liquid storage tank 14a includes a pump, not illustrated, for delivering the cutting liquid L2 from the cutting liquid storage tank 14a into the cutting liquid path 14b. When the pump is actuated and the on/off valve 14c is opened, the cutting liquid L2 is supplied from the cutting liquid storage tank 14a through the cutting liquid path 14b and the cutting liquid inlet 95a into the cutting liquid supply nozzle 95, from which the cutting liquid L2 is ejected through the ejection port 95b.

The rust inhibitor L1 according to the present embodiment will be described below. The rust inhibitor L1 includes a liquid for preventing the electrodes of the devices D produced from a workpiece, e.g., a wafer W of silicon, when it is cut, from being oxidized and rusted. The rust inhibitor L1 may be made of any of materials described below, for example.

The rust inhibitor L1 may be made of a 1,2,3-triazole derivative where no substitute is present on nitrogen atoms of a 1,2,3-triazole ring and a substitute selected from the group consisting of a hydroxy group, a carboxy group, a sulfo group, an amino group, a carbamoyl group, a carbonamide group, a sulfamoyl group, and a sulfonamide group, or an alkyl group or an aryl group substituted by at least one substrate selected from the group consisting of a hydroxy group, a carboxy group, a sulfo group, an amino group, a carbamoyl group, a carbonamide group, a sulfamoyl group, and a sulfonamide group is introduced into the fourth place and/or fifth place of 1,2,3-triazole.

Alternatively, the rust inhibitor L1 may be made of a 1,2,4-triazole derivative where no substitute is present on nitrogen atoms of a 1,2,4-triazole ring and a substitute selected from the group consisting of a sulfo group, a carbamoyl group, a carbonamide group, a sulfamoyl group, and a sulfonamide group, or an alkyl group or an aryl group substituted by at least one substrate selected from the group consisting of a hydroxy group, a carboxy group, a sulfo group, an amino group, a carbamoyl group, a carbonamide group, a sulfamoyl group, and a sulfonamide group is introduced into the second place and/or fifth place of 1,2,4-triazole.

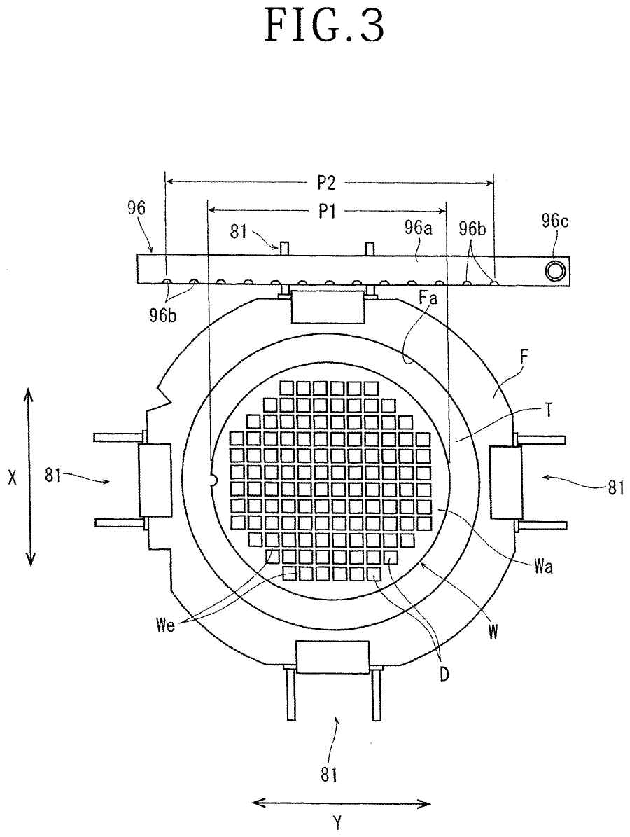

The rust inhibitor supply nozzle 96 supplies the rust inhibitor L1 such that the electrodes of the devices D on the wafer W held on the chuck table 8a will not be rusted when the wafer W is cut. The rust inhibitor supply nozzle 96 and the wafer W held on the chuck table 8a are dimensioned to satisfy the conditions to be described below with reference to FIG. 3. FIG. 3 illustrates, in plan, the wafer W held on the chuck table 8a of the holding unit 8 and the rust inhibitor supply nozzle 96 disposed adjacent to the cutting unit 9. For illustrative purposes, other structures of the cutting unit 9 such as the cover 94, the spindle housing 91, etc. than the rust inhibitor supply nozzle 96 are omitted from illustration in FIG. 3. On the wafer W, the devices D are disposed in respective areas demarcated on a face side Wa of the wafer W by a grid of projected dicing lines We. The wafer W is held on the annular frame F by the adhesive tape T and affixed to the adhesive tape T in an opening Fa of the annular frame F. When the wafer W is held on the chuck table 8a of the holding unit 8, the annular frame F is clamped by a plurality of frame clamps 81 (see also FIG. 2) mounted on the chuck table 8a and angularly spaced at predetermined intervals around the chuck table 8a. Each of the frame clamps 81 has a swingable finger 81a for clamping engagement with an outer circumferential edge portion of the annular frame F, as illustrated in FIG. 3.

As illustrated in FIG. 3, the rust inhibitor supply nozzle 96 extends along the Y-axis and has a length along the Y-axis that exceeds a width P1 of the wafer W along the Y-axis. The ejection ports 96b that are defined in the hollow cylindrical body 96a of the rust inhibitor supply nozzle 96 include an ejection port 96b at one end of the hollow cylindrical body 96a and an ejection port 96b at the other end of the hollow cylindrical body 96a. The length P2 between these ejection ports 96b at the opposite ends of the hollow cylindrical body 96a is larger than the width P1 of the wafer W. The number of the ejection ports 96b and the intervals therebetween are selected to supply the rust inhibitor L1 from the ejection ports 96b to an overall widthwise region across the wafer W on the chuck table 8a. According to the present embodiment, the rust inhibitor supply nozzle 96 supplies the rust inhibitor L1 through the ejection ports 96b defined in the hollow cylindrical body 96a. According to the present invention, however, a rust inhibitor supply nozzle may supply the rust inhibitor L1 through a slit defined therein that extends longitudinally therealong. The slit has a length in excess of the width P1 of the wafer W. The rust inhibitor supply unit 13, the cutting liquid supply unit 14, and the various other operable components of the cutting apparatus 1 are controlled by the controller mentioned above.

The cutting liquid L2 according to the present embodiment will be described below. The cutting liquid L2 includes a liquid to be supplied from the cutting liquid supply nozzle 95 to the point of contact between the cutting blade 93 and the wafer W. The cutting liquid L2 may be pure water or a mixture of an organic acid, which may be any of materials described below, and an oxidizing agent, for example.

The organic acid of the mixture to be supplied as the cutting liquid L2 from the cutting liquid supply nozzle 95 may include an amino acid such as glycine, dihydroxyethylglycine, glycylglycine, hydroxyethylglycine, N-methylglycine, β-alanine, L-alanine, L-2-aminobutyric acid, L-norvaline, L-valine, L-leucine, L-norleucine, L-alloisoleucine, L-isoleucine, L-phenylalanine, L-proline, sarcosine, L-ornithine, L-lysine, taurine, L-serine, L-threonine, L-allothreonine, L-homoserine, L-thyroxine, L-tyrosine, 3,5-diiodo-L-tyrosine, β-(3,4-dihydroxyphenyl)-L-alanine, 4-hydroxy-L-proline, L-cysteine, L-methionine, L-ethionine, L-lanthionine, L-cystathionine, L-cystine, L-cystine acid, L-glutamic acid, L-aspartic acid, S-(carboxymethyl)-L-cysteine, 4-aminobutyric acid, L-asparagine, L-glutamine, azaserine, L-canavanine, L-citrulline, L-arginine, 5-hydroxy-L-lysine, creatine, L-kynurenine, L-histidine, 1-methyl-L-histidine, 3-methyl-L-histidine, L-tryptophane, actinomycin Cl, ergothioneine, apamin, angiotensin I, angiotensin II, antipain, or the like. Among these materials are preferable glycine, L-alanine, L-proline, L-histidine, L-lysine, and dihydroxyethyl-glycine.

The organic acid of the mixture may include an amino polyacid such as iminodiacetic acid, nitrilotriacetic acid, diethylenetriaminepentaacetic acid, ethylenediaminetetraacetic acid, hydroxyethyl-iminodiacetic acid, nitrilotrismethylene phosphonic acid, ethylenediamine-N,N,N′,N′-tetramethylene phosphonic acid, 1,2-diaminopropanetetraacetic acid, glycoletherdiamnine-tetraacetic acid, transcyclohexanediaminetetraacetic acid, ethylenediamineorthohydroxyphenylacetic acid, ethylenediaminesuccinic acid (SS), β-alanidinacetic acid, N-(2-carboxylateethyl)-L-aspartic acid, N,N′-bis(2-hydroxybenzyl)ethlenediamine-N,N′-diacetic acid, or the like.

Moreover, the organic acid of the mixture may include a carboxylic acid such as a saturated carboxylic acid including formic acid, glycolic acid, propionic acid, acetic acid, butyric acid, hexanoic acid, oxalic acid, malonic acid, glutaric acid, adipic acid, malic acid, succinic acid, pimelic acid, mercaptoacetic acid, glyoxylic acid, chloroacetic acid, pyruvic acid, acetoacetic acid, glutaric acid, or the like, or an unsaturated carboxylic acid such as acrylic acid, methacrylic acid, crotonic acid, fumaric acid, maleic acid, mesaconic acid, citraconic acid, aconitic acid, or the like, or a cyclic unsaturated carboxylic acid such as benzoic acids, toluic acid, phthalic acids, naphthoic acids, pyromellitic acid, naphthalic acid, or the like.

The oxidizing agent of the mixture supplied from the cutting liquid supply nozzle 95 may include, for example, hydrogen peroxide, peroxide, nitrate, iodate, periodate, hypochlorite, chlorite, chlorate, perchlorate, persulfate, dichromate, permanganate, cerium acid salt, vanadate, ozonated water, silver (II) salt, or iron (III) salt, or its organic complex salt or the like.

The mixture of an organic acid and an oxidizing agent that is used as the cutting liquid L2 functions to prevent scattered swarf from being deposited on the face side Wa of the wafer W held on the chuck table 8a when the wafer W is cut, and to remove burrs formed on the devices D individually divided from the wafer W when it is cut. Therefore, the quality of the devices D is prevented from being lowered. The cutting liquid L2 may be mixed with the rust inhibitor L1.

The cutting apparatus 1 according to the present embodiment is basically of the structure described above. Now, a process of cutting a wafer W as a workpiece on the cutting apparatus 1 will be described below. As described above, the workpiece to be cut by the cutting apparatus 1 is a plate-shaped wafer W of silicon with devices D constructed in respective areas demarcated on a face side Wa by a grid of projected dicing lines We.

For cutting the wafer W with the cutting unit 9 of the cutting apparatus 1, a wafer W stored in the cassette 4 is unloaded from the cassette 4 onto the temporary support table 5 by the unloading and loading unit 6. Then, the wafer W is delivered by the delivery unit 7 onto the chuck table 8a that has been positioned in an unloading and loading position illustrated in FIG. 1. After the wafer W has been placed and held under suction on the chuck table 8a, the holding unit 8 and hence the wafer W are moved to the position directly below the cutting unit 9 by the X-axis feed mechanism, not illustrated. The image capturing unit 12 then captures an image of the wafer W, and detects one of the parallel projected dicing lines We extending in a first direction from the captured image. The holding unit 8 is turned to align the detected projected dicing line We with the X-axis. The projected dicing line We and the cutting blade 93 are then aligned with each other, and the cutting unit 9 is positioned in a predetermined processing start position.

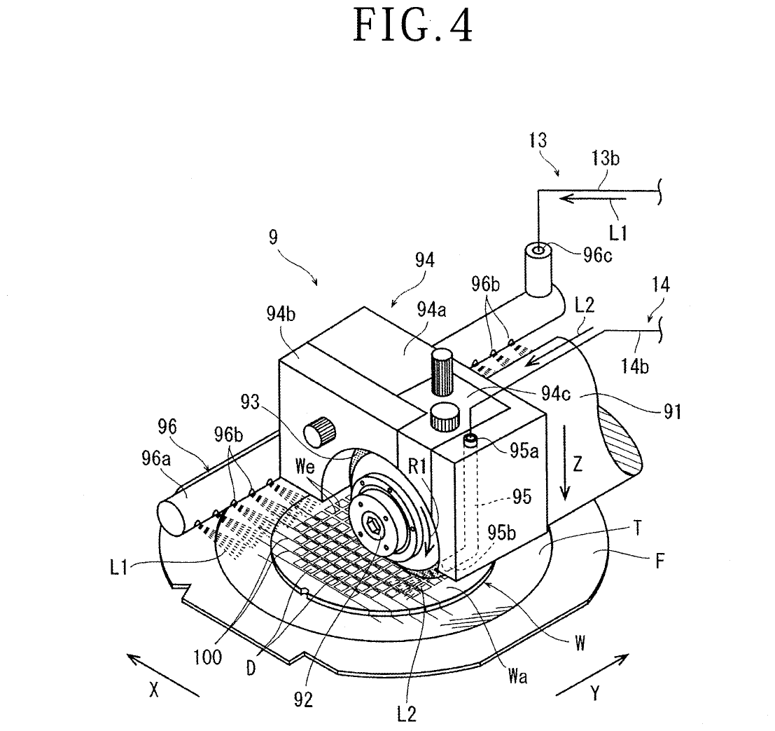

Then, as illustrated in FIG. 4, the cutting blade 93 is rotated about its central axis at a high speed in the direction indicated by the arrow R1, and is placed above the projected dicing line We extending in the first direction aligned with the X-axis. The rust inhibitor supply unit 13 and the cutting liquid supply unit 14 are actuated to eject the rust inhibitor L1 and the cutting liquid L2 respectively from the rust inhibitor supply nozzle 96 and the cutting liquid supply nozzle 95. Then, the Z-axis feed mechanism, not illustrated, is actuated to lower the cutting blade 93 in the direction indicated by the arrow Z along the Z-axis to cut into the wafer W from the face side Wa, and at the same time, the X-axis feed mechanism, not illustrated, is actuated to processing-feed the wafer W in the direction indicated by the arrow X along the X-axis, thereby forming a cut groove 100 in the wafer W. According to the present invention, the cutting liquid L2 ejected from the cutting liquid supply nozzle 95 is a mixture of an organic acid and an oxidizing agent as described above. However, the cutting liquid L2 may be pure water.

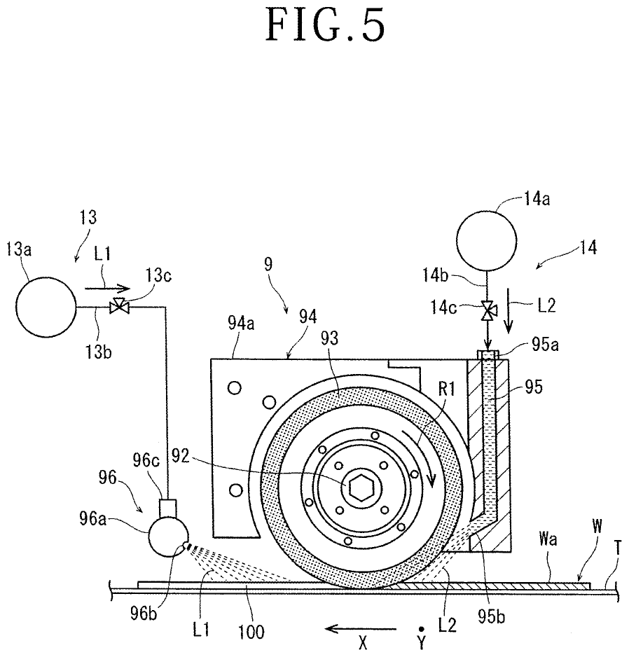

FIG. 5 illustrates, in front elevation, partly in cross section, the manner in which the cutting process is carried out to form the cut groove 100. In FIG. 5, for illustrative purposes, the second cover member 94b and the blade detecting block 94c of the cover 94 are omitted from illustration, and the first cover member 94a in which the cutting liquid supply nozzle 95 is disposed is illustrated partly in cross section.

After the cut groove 100 has been formed in the wafer W, the Y-axis feed mechanism, not illustrated, indexing-feeds the cutting blade 93 along the Y-axis to a position above a next projected dicing line We where the wafer W has not been processed that is positioned adjacent to the projected dicing line We along which the cut groove 100 has been formed in the wafer W. Then, the cutting blade 93 forms a cut groove 100 in the wafer W along the next projected dicing line We in the same fashion as described above. The cutting unit 9 and the holding unit 8 repeat the above process until cut grooves 100 are formed in the wafer W along all the projected dicing lines We that extend in the first direction along the X-axis. Then, the holding unit 8 and hence the wafer W are turned 90 degrees about their central axes to align the projected dicing lines We that extend in a second direction perpendicular to the first direction with the X-axis. While the rust inhibitor L1 and the cutting liquid L2 are being supplied to the point of contact between the cutting blade 93 and the wafer W, the cutting unit 9 forms cut grooves 100 in the wafer W along all the projected dicing lines We that extend in the second direction along the X-axis. In this manner, the cut grooves 100 are formed in the wafer W along all the projected dicing lines We extending in the first and second directions on the wafer W. The areas of the wafer W where the devices D are constructed are now divided into individual device chips along the cut grooves 100.

As illustrated in FIGS. 4 and 5, since the rust inhibitor supply nozzle 96 supplies the rust inhibitor L1 to the face side Wa of the wafer W, the electrodes of the devices D are prevented from being oxidized and rusted. Therefore, the problem of a reduction in the quality of the devices D due to rust on the electrodes is eliminated. If the cutting liquid L2 supplied from the cutting liquid supply nozzle 95 to the point of contact between the cutting blade 93 and the wafer W is a mixture of an organic acid and an oxidizing agent as described above, then the cutting liquid L2 functions to prevent scattered swarf from being deposited on the face side Wa of the wafer W and to remove burrs formed on the devices D individually divided from the wafer W when it is cut.

According to the present invention, the workpiece to be cut is not limited to the wafer W according to the embodiment described above. The workpiece may be a packaged substrate having a plurality of devices referred to as QFN, for example. When such a packaged substrate is cut along projected dicing lines by the cutting apparatus 1, the packaged substrate is divided into a plurality of device chips having respective devices that include exposed electrodes on their outer sides. Inasmuch as the cutting apparatus 1 supplies the rust inhibitor L1 and the cutting liquid L2, the exposed electrodes of the devices are prevented from being oxidized and rusted, and the devices are prevented from being lowered in quality.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus comprising:
a chuck table for holding thereon a workpiece having a plurality of devices including electrodes that are constructed in respective areas demarcated on a face side of the workpiece by a plurality of projected dicing lines;
a cutting unit having a rotatable cutting blade for cutting the workpiece held on the chuck table;
an X-axis feed mechanism for cutting-feeding the chuck table and the cutting unit relatively to each other along an X-axis;
a Y-axis feed mechanism for indexing-feeding the chuck table and the cutting unit relatively to each other along a Y-axis perpendicular to the X-axis;
a cutting liquid supply nozzle disposed adjacent to the cutting unit, for supplying a cutting liquid to a point of contact between the cutting blade and the workpiece; and
a rust inhibitor supply nozzle for supplying a rust inhibitor to the workpiece on the chuck table to prevent the electrodes of the devices from being rusted, the rust inhibitor supply nozzle having a length along the Y-axis in excess of the width of the workpiece along the Y-axis.

2. The cutting apparatus according to claim 1, wherein the cutting liquid supply nozzle supplies pure water or a mixture of an organic acid and an oxidizing agent as the cutting liquid.
